(19) United States
(12) Patent Application Publication
(10) Pub. No.: US 2019/0055666 A1
(43) Pub. Date: Feb. 21, 2019

(54) SILICON SINGLE CRYSTAL INGOT COOLING TUBE AND SILICON SINGLE CRYSTAL INGOT GROWTH APPARATUS HAVING THE SAME

(71) Applicant: SK Siltron Co., Ltd., Gumi-si Gyeongsangbuk-do (KR)

(72) Inventors: Jung Ha HWANG, Gumi-si (KR); In Gu KANG, Gumi-si (KR); So Young JEON, Gumi-si (KR)

(73) Assignee: SK SILTRON CO., LTD.

(21) Appl. No.: 15/873,640

(22) Filed: Jan. 17, 2018

(30) Foreign Application Priority Data
Aug. 18, 2017 (KR) 10-2017-0104709

(51) Int. Cl. C30B 15/14; C30B 15/20

(52) U.S. Cl. CPC C30B 15/14; C30B 29/06; C30B 15/20

(57) ABSTRACT

The present invention provides a silicon single crystal ingot cooling tube, including: an inner wall portion for forming a hollow into which a silicon single crystal ingot is inserted; an outer wall portion spaced apart from the inner wall portion and surrounding the inner wall portion from outside; a top wall portion and a bottom wall portion for sealing a space portion formed by the inner wall portion and the outer wall portion; at least one cooling water inlet tube for introducing cooling water into the space portion; at least one cooling water outlet tube for discharging cooling water flowing along the space portion; and a cooling water flowing portion for flowing cooling water introduced along the cooling water inlet tube to an upper region of the space portion from a lower region thereof and discharging cooling water to the cooling water outlet tube.

### CROSS REFERENCE TO RELATED APPLICATION

This application claims priority under 35 U.S.C. § 119 to Korean Patent Application No. 10-2017-0104709 filed in Korea on 18 Aug. 2017 which is hereby incorporated in its entirety by reference as if fully set forth herein.

### TECHNICAL FIELD

The present invention relates to a semiconductor manufacturing apparatus, and more particularly, to a silicon single crystal ingot growth apparatus to be a material of a semiconductor substrate.

### BACKGROUND

A wafer which is widely used as a material for fabricating a semiconductor device is produced as a wafer through steps of a slicing process for thinly cutting a silicon single crystal ingot into a wafer shape, a lapping process for improving flatness while polishing to a desired thickness, an etching process for removing a damaged layer inside a wafer, a polishing process for improving mirroring and flatness on a wafer surface, a cleaning process for removing contaminants on a wafer surface, and the like.

A silicon single crystal ingot is generally grown and fabricated according to the Czochralski method. Such a method is a method of melting polysilicon in a crucible in a chamber and immersing a seed crystal, which is a single crystal, into molten silicon and then gradually pulling up and growing the seed crystal into a silicon single crystal ingot having a desired diameter.

FIG. 1 is a configuration diagram of a general silicon single crystal ingot growth apparatus.

As shown in FIG. 1, first, a silicon melt SM is formed by stacking polysilicon and a dopant on a quartz crucible 20 provided inside a chamber 10 and melting the polysilicon and the dopant by a heater 40 provided around a sidewall of the quartz crucible 20. Subsequently, a silicon single crystal ingot IG is grown by submerging a seed crystal, which is a growth source of the silicon single crystal ingot IG, in a surface of the silicon melt SM and then gradually pulling up the seed crystal while rotating the seed crystal in a predetermined direction by using a pulling unit 80.

Meanwhile, in order to cool down a growing silicon single crystal ingot IG of a high temperature, a single crystal ingot cooling tube 100 is provided in a shape of surrounding the single crystal ingot IG in an upper region of the chamber 10.

The single crystal ingot cooling tube 100 is formed in a double tube shape in which the inside thereof is sealed so as to form a space through which cooling water flows.

FIG. 2 is a development view illustrating an inner space region of a single crystal ingot cooling tube.

As shown in FIG. 2, a cooling water flowing space may be divided left and right by an inner wall 120 of the single crystal ingot cooling tube 100, and the flowing space may be divided again by a partition wall 130 into a space where cooling water is flowing downward and a space where cooling water is flowing upward. In addition, the single crystal ingot cooling tube 100 is formed with an inlet 140 for introducing cooling water into an inner space and an outlet 160 for discharging cooling water flowing in the inner space to outside.

Therefore, the cooling water introduced by the cooling water inlet 140 may flow into a flowing space and be discharged to the cooling water outlet 160 while flowing downward and upward again as shown by an arrow.

However, since cooling water flowing inside the single crystal ingot cooling tube absorbs heat emitted from the single crystal ingot, a temperature for each part is different, and thus a difference occurs in cooling efficiency. In addition, when cooling water flowing inside the single crystal ingot cooling tube switches a direction of flowing upward to downward or downward to upward, bubbles may be generated, and thus cooling efficiency is adversely affected.

### SUMMARY

The present invention is directed to providing a silicon single crystal ingot cooling tube capable of uniformly cooling down a temperature of a single crystal ingot in a radial direction and a vertical direction, and of eliminating cooling imbalance due to bubble generation, and a silicon single crystal ingot growth apparatus having the same.

The present invention provides a silicon single crystal ingot cooling tube, including: an inner wall portion for forming a hollow into which a silicon single crystal ingot is inserted; an outer wall portion spaced apart from the inner wall portion and surrounding the inner wall portion from outside; a top wall portion and a bottom wall portion for sealing a space portion formed by the inner wall portion and the outer wall portion; at least one cooling water inlet tube for introducing cooling water into the space portion; at least one cooling water outlet tube for discharging cooling water flowing along the space portion; and a cooling water flowing portion for flowing cooling water introduced along the cooling water inlet tube to an upper region of the space portion from a lower region thereof and discharging cooling water to the cooling water outlet tube.

The cooling water flowing portion may include a downward guide for guiding the cooling water introduced into the cooling water inlet tube to a lower portion of the space portion; and an upward guide for flowing the cooling water introduced into the downward guide in a zigzag shape toward an upper portion of the space portion from the lower portion thereof.

The downward guide may include a first vertical wall for dividing the space portion in a vertical direction; a vertical partition wall disposed in parallel with the first vertical wall so as to be adjacent to the upward guide; and a horizontal partition wall extending from the vertical partition wall and disposed in parallel with the bottom wall portion.

A width of the downward guide may be the same as a width of the cooling water inlet tube.

The upward guide may include a second vertical wall for dividing the space portion in a vertical direction; a plurality of first horizontal walls each extending in a horizontal direction along a longitudinal direction of the vertical partition wall; and a plurality of second horizontal walls each extending in a horizontal direction along a longitudinal direction of the second vertical wall and disposed between the first horizontal walls.

An interval between the first horizontal walls adjacent to each other may be gradually increased as toward an upper portion.

An interval between the first horizontal walls may be gradually increased by a width of 10 to 15% as toward an upper portion.

The first horizontal walls may be spaced apart from the second vertical wall, and the second horizontal walls may be spaced apart from the vertical partition wall.

The first horizontal walls may have the same length as that of the second horizontal walls, or the length of the second horizontal walls may be shorter than that of the first horizontal walls.

The upward guide may be disposed in a horizontal direction so as to be spaced apart from the vertical partition wall along the longitudinal direction of the vertical partition wall, and further include a plurality of first horizontal spacing walls disposed on an upper portion of the first horizontal walls.

An end portion of the first horizontal spacing wall adjacent to the vertical partition wall may be bent downward.

The upward guide may be disposed in a horizontal direction so as to be spaced apart from the second vertical wall along the longitudinal direction of the second vertical wall and further include a plurality of second horizontal spacing walls disposed on an upper portion of the first horizontal spacing walls.

An end portion of the second horizontal spacing wall adjacent to the second vertical wall may be bent downward.

A plurality of the cooling water flowing portions may be disposed adjacent to the space portion.

The cooling water inlet tube and the cooling water outlet tube may be coupled to an upper side of the outer wall portion.

Meanwhile, the present invention provides a silicon single crystal ingot cooling tube, including: an inner wall portion for forming a hollow; an outer wall portion spaced apart from the inner wall portion and surrounding the inner wall portion from outside; a top wall portion and a bottom wall portion for sealing a space portion formed by the inner wall portion and the outer wall portion; at least one cooling water inlet tube located in an upper portion of the outer wall portion and introducing cooling water into the space portion; at least one cooling water outlet tube located in the upper portion of the outer wall portion and discharging cooling water flowing along the space portion; a downward guide for forming a flow path for guiding the cooling water introduced into the cooling water inlet tube to a lower portion of the space portion; and a upward guide for forming a flow path for discharging the cooling water to the cooling water outlet tube by flowing the cooling water introduced into the downward guide in a zigzag shape toward an upper portion of the space portion from the lower portion thereof.

The silicon single crystal ingot cooling tube may further include a first vertical wall for dividing the space portion in a vertical direction; a vertical partition wall disposed in parallel with the first vertical wall so as to be adjacent to the upward guide; and a horizontal partition wall extending from the vertical partition wall and disposed in parallel with the bottom wall portion.

The silicon single crystal ingot cooling tube may further include a second vertical wall for dividing the space portion in a vertical direction and disposed apart from the first vertical wall; a plurality of first horizontal walls each extending in a horizontal direction along a longitudinal direction of the vertical partition wall; and a plurality of second horizontal walls each extending in a horizontal direction along a longitudinal direction of the second vertical wall and disposed between the first horizontal walls.

The silicon single crystal ingot cooling tube may be disposed in a horizontal direction so as to be spaced apart from the vertical partition wall along the longitudinal direction of the vertical partition wall, and further include a plurality of first horizontal spacing walls disposed on an upper portion of the first horizontal walls.

The silicon single crystal ingot cooling tube may be disposed in a horizontal direction so as to be spaced apart from the second vertical wall along the longitudinal direction of the second vertical wall and further include a plurality of second horizontal spacing walls disposed on an upper portion of the first horizontal spacing walls.

The downward guide and the upward guide may be disposed in plural adjacent to the space portion.

Meanwhile, the present invention provides a single crystal growth apparatus including: a chamber; a crucible disposed inside the chamber and accommodating a silicon melt; and the above-described silicon single crystal ingot cooling tube for performing cooling down of a silicon single crystal ingot growing from the crucible.

### BRIEF DESCRIPTION OF THE DRAWINGS

FIG. 1 is a configuration diagram of a general silicon single crystal ingot growth apparatus.

FIG. 2 is a development view illustrating an inner space region of a single crystal ingot cooling tube.

FIG. 3 is a configuration diagram of a silicon single crystal ingot growth apparatus according to an embodiment of the invention.

FIG. 4 is a perspective view of a silicon single crystal ingot cooling tube of an embodiment.

FIGS. 5 and 6 are development views illustrating an inner structure of a region A-B of FIG. 4.

FIG. 7 is a development view of a silicon single crystal ingot cooling tube of another embodiment.

FIG. 8 is a development view of a silicon single crystal ingot cooling tube of still another embodiment.

FIG. 9 is a graph illustrating a temperature distribution of locations in vertical and radial directions of a silicon single crystal ingot cooling tube of the present embodiment.

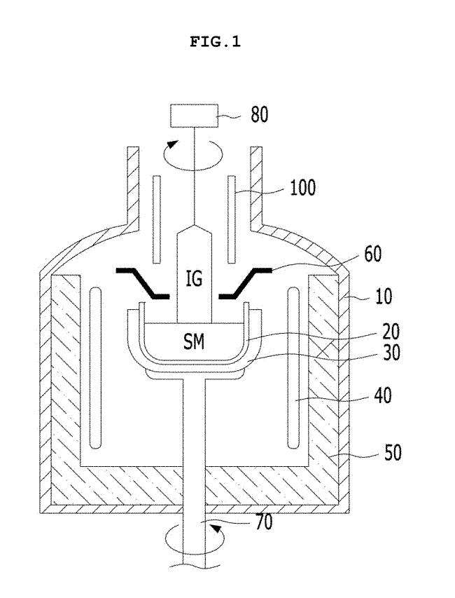

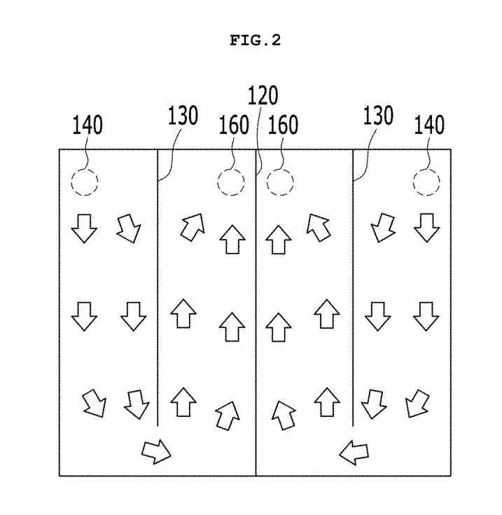

### DETAILED DESCRIPTION OF THE EMBODIMENTS

Hereinafter, embodiments will be shown more apparently through the description of the appended figures and the embodiments. In the description of the embodiment, when it is described that each layer (film), region, pattern, or structure is formed “above/on” or “below/under” a substrate, each layer (film), region, pad or pattern, being formed “above/on” and “below/under” includes being formed both “directly” or “indirectly (by interposing another layer)”. Also, a standard of above/on or below/under of each layer will be described with respect to the drawings.

Areas in the drawings may be exaggerated, omitted, or schematically described for a convenient and precise description. In addition, the size of each component does not fully match the actual size thereof. Further, the same reference numbers represent the same elements through description of the drawings. Hereinafter, an embodiment will be described with reference to the accompanying drawings.

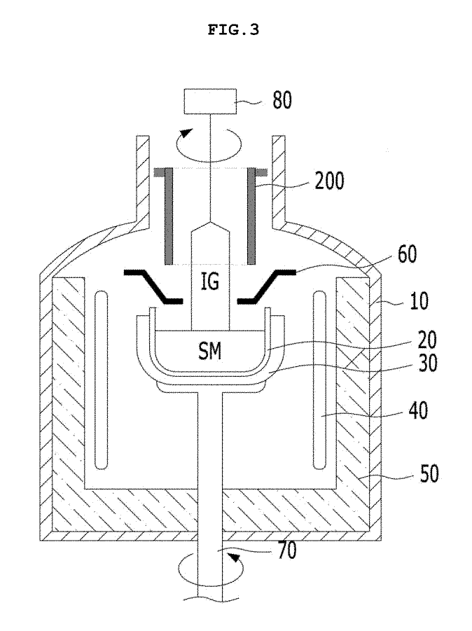

FIG. 3 is a configuration diagram of a silicon single crystal ingot growth apparatus according to an embodiment of the invention.

As shown in FIG. 3, a silicon single crystal ingot growth apparatus according to an embodiment may include a chamber 10, a crucible 20, a crucible support 30, a heater 40, a heat insulating unit 50, a heat shield unit 60, a crucible rotating unit 70, a pulling unit 80, and a cooling tube 100.

The chamber 10 forms a space for growing a silicon single crystal ingot IG. The crucible 20 is installed inside the chamber 10 and accommodates silicon melt SM which is melted at a high temperature.

The crucible support 30 supports the crucible 20 while surrounding an outer circumferential surface of the crucible 20. The crucible rotating unit 70 for moving the crucible 20 upward or downward while rotating the crucible 20 and the crucible support 30 is located at a lower end of the crucible support 30.

The heater 40 is installed around a sidewall of the crucible 20 and heats the crucible 20. The heat insulating unit 50 is disposed at an outer side of the heater 40 and prevents heat generated from the heater 40 from leaking to outside.

The heat shield unit 60 is located in an upper portion of the crucible 20 and blocks heat radiating to a silicon single crystal ingot IG growing from silicon melt SM.

A pulling unit 150 rotates in a predetermined direction and pulls up a silicon single crystal ingot IG from silicon melt SM accommodated in the crucible 20 by using a seed crystal.

A cooling tube 200 is located in a hot zone in the chamber 10 so that a silicon single crystal ingot IG, which is pulled up and grown by the pulling unit 150 from silicon melt SM accommodated in the crucible 20, is cooled down while passing through the inside of the cooling tube 200.

The cooling tube 200 is disposed to surround an ingot IG to cool down a silicon single crystal ingot IG, and cooling water is circulated inside the cooling tube 200 in a balanced manner.

According to the present embodiment, the cooling tube 200 may uniformly cool down a temperature of the single crystal ingot in a radial direction and a vertical direction, and thus cooling imbalance due to bubble generation may be solved by removing bubbles of cooling water. Hereinafter, the silicon single crystal ingot cooling tube 200 of an embodiment providing the above-mentioned effect will be described in more detail.

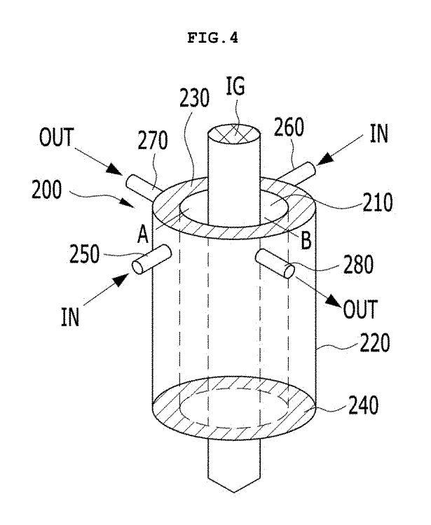

FIG. 4 is a perspective view of a silicon single crystal ingot cooling tube of an embodiment.

As shown in FIG. 4, the silicon single crystal ingot cooling tube 200 of an embodiment may be in a double tube shape sealed inside including an inner wall portion 210, an outer wall portion 220, a top wall portion 230, and a bottom wall portion 240.

The inner wall portion 210 may form a hollow into which a silicon single crystal ingot IG is inserted. For example, a diameter of a hollow formed by the inner wall portion 210 may be greater than that of an ingot IG so that the ingot IG may be inserted.

The outer wall portion 220 is spaced apart from the inner wall portion 210 and is disposed to surround the inner wall portion 210 from outside. For example, the outer wall portion 220 may be disposed on an outer side of the inner wall portion 210 at a predetermined distance separated from the inner wall portion 210 so as to have concentric circles around a hollow shaft. A space is formed by a distance separated between the outer wall portion 220 and the inner wall portion 210.

The top wall portion 230 and the bottom wall portion 240 seal a space portion formed by the inner wall portion 210 and the outer wall portion 220. That is, the top wall portion 230 seals an upper region of the space portion, and the bottom wall portion 240 seals a lower region of the space portion.

Cooling water inlet tubes 250 and 260 and cooling water outlet tubes 270 and 280 are mounted on the cooling tube 200 described above.

The cooling water inlet tubes 250 and 260 may introduce cooling water into the space portion of the cooling tube 200. For example, at least one of the cooling water inlet tubes 250 and 260 may be installed in an upper region of the outer wall portion 220. Although two cooling water inlet tubes 250 and 260 are disposed as shown in an embodiment, the number of the cooling water inlet tubes 250 and 260 may be one, three, four or more, and a disposing distance, disposing location, or the like may be modified.

The cooling water outlet tubes 270 and 280 may discharge cooling water flowing along the space portion of the cooling tube 200 to outside. For example, at least one of the cooling water outlet tubes 270 and 280 may be installed in the upper region of the outer wall portion 220. Similarly, although two cooling water outlet tubes 270 and 280 are arranged alternately with the two cooling water inlet tubes 250 and 260 as shown in an embodiment, the cooling water outlet tubes 270 and 280 may be one, three, four or more, and a disposing distance, and disposing location, or the like such as the cooling water outlet tubes 270 and 280 disposed adjacent to each other, or the cooling water inlet tubes 250 and 260 disposed adjacent to each other may be modified.

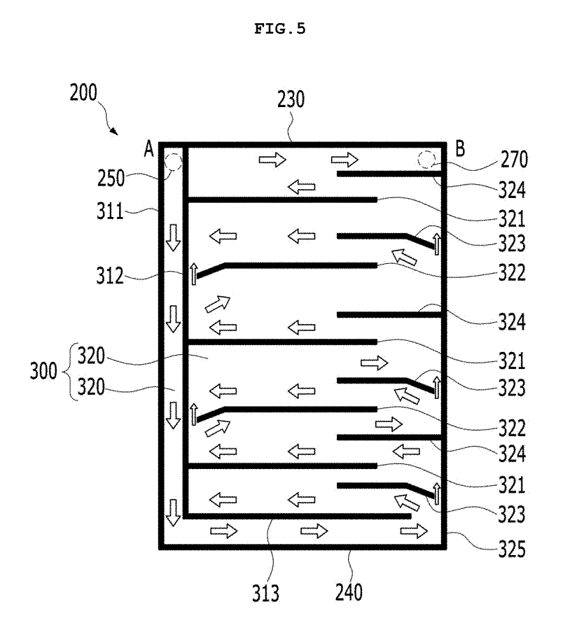

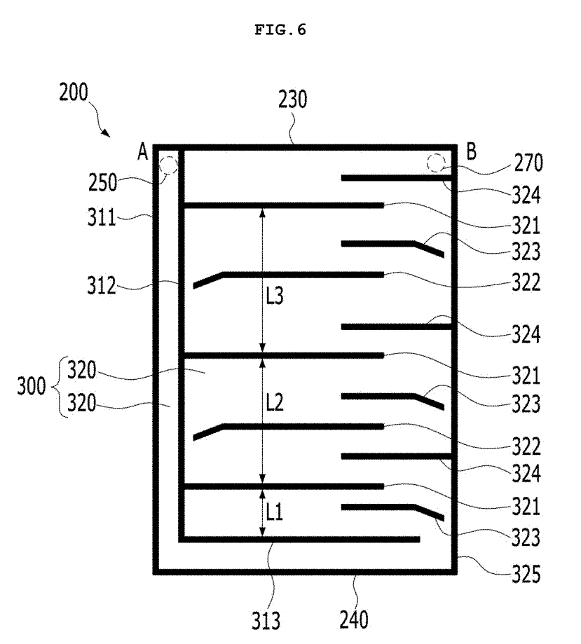

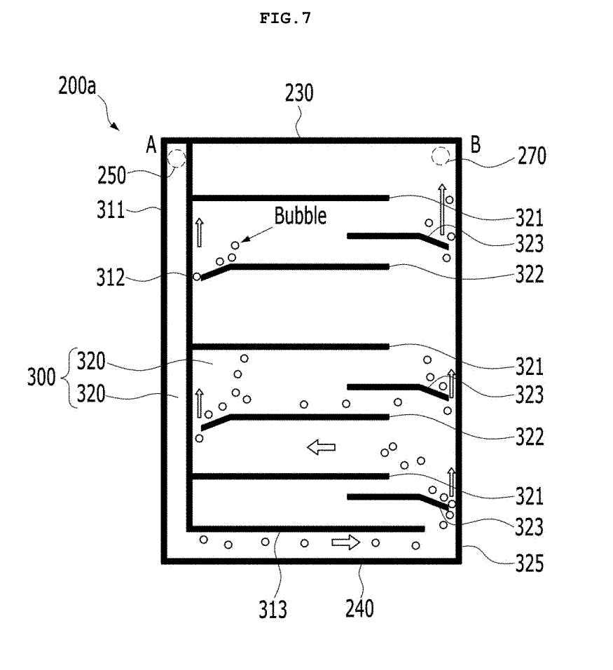

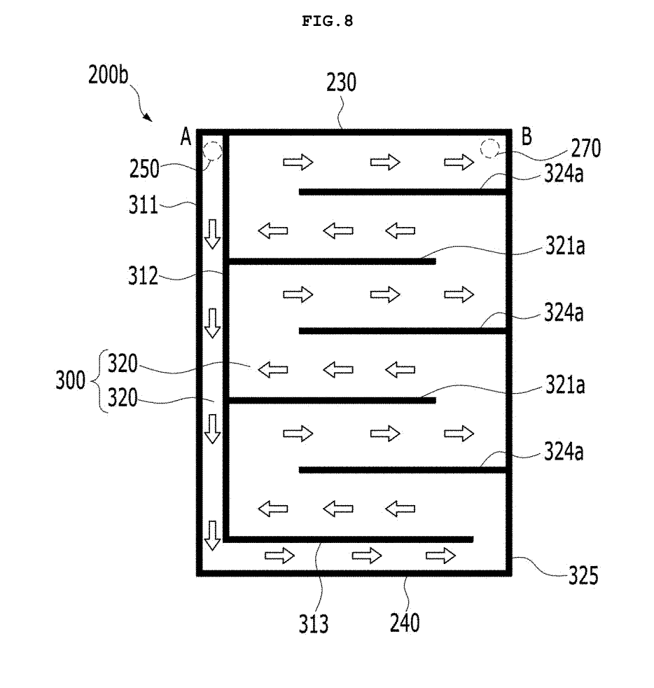

FIGS. 5 and 6 are development views illustrating an inner structure of a region A-B of FIG. 4, FIG. 7 is a development view of a silicon single crystal ingot cooling tube of another embodiment, and FIG. 8 is a development view of a silicon single crystal ingot cooling tube of still another embodiment.

As shown in FIGS. 5 and 6, according to an embodiment, the cooling tube 200 may include a cooling water flowing portion 300 for flowing the cooling water introduced along the cooling water inlet tubes 250 and 260 from the lower region of the space portion to the upper region thereof and for discharging the cooling water to the cooling water outlet tubes 270 and 280.

The cooling water flowing portion 300 may include a downward guide 310 for flowing cooling water downward from an upper portion to a lower portion, and an upward guide 320 for flowing cooling water upward from the lower portion to the upward portion.

The downward guide 310 may form a flow path for guiding cooling water introduced into the cooling water inlet tubes 250 and 260 to the lower portion of the space portion. For example, the downward guide 310 may form a flow path in the space portion via a first vertical wall 311, a vertical partition wall 312, and a horizontal partition wall 313.

The first vertical wall 311 may divide the space portion in a vertical direction. For example, the first vertical wall 311 is formed in a plate shape, so that the first vertical wall 311 may connect the inner wall portion 210 and the outer wall portion 220, and be vertically disposed on the inner wall portion 210 and the outer wall portion 220 to connect the top wall portion 230 and the bottom wall portion 240.

The vertical partition wall 312 may be disposed in parallel with the first vertical wall 311 so as to be adjacent to the downward guide 310. For example, the vertical partition wall 312 may be formed in a plate shape, so that the vertical partition wall 312 may be spaced apart from the first vertical wall 311 at a predetermined distance, connect the inner wall portion 210 and the outer wall portion 220, and be vertically disposed to be connected to the top wall portion 230. The vertical partition wall 312 may have a shorter length than that of the first vertical wall 311 so as to be spaced apart from the bottom wall portion 240 at a predetermined distance.

The horizontal partition wall 313 may extend from the vertical partition wall 312 and may be disposed in parallel with the bottom wall portion 240. For example, the horizontal partition wall 313 may be formed in a plate shape so that the horizontal partition wall 313 may extend horizontally at an end portion of the vertical partition wall 312 and connect the inner wall portion 210 and the outer wall portion 220.

The above-described downward guide 310 is communicated with the cooling water inlet tubes 250 and 260. As shown in FIG. 5, cooling water introduced into the cooling water inlet tubes 250 and 260 can be guided downward by forming a flow path for flowing the cooling water from an upper portion to a lower portion as shown by an arrow.

A width of a flow path of the downward guide 310 may be the same as that of the cooling water inlet tubes 250 and 260 so as to increase a flow rate of cooling water and to increase cooling efficiency.

The upward guide 320 may flow cooling water introduced into the above-described downward guide 310 in a zigzag shape toward the upper portion of the space portion from the lower portion thereof. Here, a zigzag shape may refer that cooling water is flowing from a left direction to a right direction in turns. As described above, the upward guide 320 allows cooling water to flow uniformly in a radial direction of the cooling tube 200 while the cooling water flows in a zigzag shape and thereafter forms a flow path capable of flowing the cooling water upward.

For example, the upward guide 320 may be formed via a second vertical wall 325, a first horizontal wall 321, and a second horizontal wall 324.

The second vertical wall 325 may divide the space portion in a vertical direction. For example, the second vertical wall 325 may be formed in a plate shape like the first vertical wall 311 to connect the inner wall portion 210 and the outer wall portion 220, and may be vertically disposed on the inner wall portion 210 and the outer wall portion 220 to connect the top wall portion 230 and the bottom wall portion 240. The second vertical wall 325 is spaced apart from the first vertical wall 311 (in the present embodiment, located on the right side of the first vertical wall 311) and forms an outer wall of the upward guide 320.

The second vertical wall 325 may be disposed adjacent to another upward guide 320, and the cooling water flowing portion 300 may be connected in plural. Accordingly, the first vertical wall 311 connected to the upward guide 320 and adjacent thereto may function as the second vertical wall 325.

The first horizontal wall 321 may extend in a horizontal direction along a longitudinal direction of the vertical partition wall 312 of the downward guide 310, and the first horizontal wall 321 may be formed in plural. Here, the first horizontal walls 321 may have a length spaced apart from the second vertical wall 325. Accordingly, cooling water may flow between the first horizontal walls 321 and the second vertical wall 325.

The second horizontal wall 324 may extend in a horizontal direction along a longitudinal direction of the second vertical wall 325, and may be disposed in plural between the first horizontal walls 321. Here, the second horizontal walls 324 may have a length spaced apart from the vertical partition wall 312 of the downward guide 310. Accordingly, cooling water may flow between the second horizontal walls 324 and the vertical partition wall 312.

As such, the first horizontal walls 321 and the second horizontal walls 324 are disposed such that the flow paths are disposed alternately, thereby forming a passage through which cooling water can flow in a zigzag shape (stepped shape).

Here, the first horizontal walls 321 and the second horizontal walls 324 may have the same length, or a length of the second horizontal walls 324 may be shorter than that of the first horizontal walls 321 as shown in FIGS. 5 and 6. The same lengths of first horizontal walls 321a and second horizontal walls 324a, including the upward guide 320 of the above-described configuration can constitute an embodiment as shown in FIG. 8.

Meanwhile, as shown in FIG. 6, an interval between the first horizontal walls 321 adjacent to each other may be disposed to be gradually increased toward an upper portion.

Likewise, an interval between the second horizontal walls 324 adjacent to each other is disposed to be gradually increasing as toward an upper portion.

As described above, the downward guide 310 may gradually expand a passage through which cooling water flows. For example, the interval between the first horizontal walls 321 may be increased in width by 10 to 15% (L1<L2<L3) as toward an upper portion. This is because as a flow rate of cooling water gradually decreases toward an upper portion, a temperature deviation of cooling water in upper and lower portions (because a temperature of a lower portion of an ingot (IG) is higher than that of an upper portion thereof) may be reduced, and occurrence of bubbles may be reduced by gradually decreasing a flow rate.

Meanwhile, the upward guide 320 may further include a plurality of first horizontal spacing walls 322 and a plurality of second horizontal spacing walls 323.

The first horizontal spacing wall 322 may be disposed in a horizontal direction to be spaced apart from the vertical partition wall 312 along the longitudinal direction of the vertical partition wall 312, and may be disposed in an upper portion of the first horizontal walls 321. For example, the first horizontal spacing wall 322 may be formed in a plate shape so that the first horizontal spacing wall 322 may be installed to connect the inner wall portion 210 and the outer wall portion 220 in a horizontal direction.

At this point, an end portion of the first horizontal spacing wall 322 adjacent to the vertical partition wall 312 may be bent downward. Since an end portion of the first horizontal spacing wall 322 is spaced apart from the vertical partition wall 312 in a state where the end portion of the first horizontal spacing wall 322 is bent downward, a small flow path through which cooling water may flow may be formed. Even if bubbles are generated by a narrow flow path adjacent to a shape of the end portion of the first horizontal spacing wall 322 while cooling water flows in the left direction in the upward guide 320, as shown in FIG. 7, the bubbles may be squashed to a small size or the bubbles may be removed by colliding with the end portion of the first horizontal spacing wall 322.

The second horizontal spacing wall 323 is disposed in a horizontal direction to be spaced apart from the second vertical wall 325 along the longitudinal direction of the second vertical wall 325, and may be disposed on an upper portion of the first horizontal spacing walls 322. For example, the second horizontal spacing wall 323 may be formed in a plate shape like the first horizontal spacing wall 322 so that the second horizontal spacing wall 323 may be installed to connect the inner wall portion 210 and the outer wall portion 220 in a horizontal direction.

In addition, an end portion of the second horizontal spacing wall 323 adjacent to the second vertical wall 325 may be bent downward. Therefore, even if bubbles are generated by a narrow flow path adjacent to a shape of the end portion of the second horizontal spacing wall 323 while cooling water flows in the right direction in the upward guide 320, as shown in FIG. 7, the bubbles may be squashed to a small size or the bubbles may be removed by colliding with the end portion of the first horizontal spacing wall 322.

The upward guide 320 including the above-described components may have a circulation structure in which the cooling water moves upward while moving in a zigzag shape as shown in FIG. 5 and is discharged to outside via a cooling water outlet.

As described above, since the cooling water flowing portion 300 may be supplied with cooling water from an upper portion to a lower portion by the downward guide 310, and the cooling water moves upward in a zigzag shape by the upward guide 320, a temperature of a single crystal ingot IG may be uniformly cooled down in a radial direction and a vertical direction, and thus cooling imbalance due to bubble generation can be solved by removing bubbles via a bubble removing inlet hole.

A plurality of the above-described cooling water flowing portions 300 may be disposed adjacent to a space portion of the cooling tubes 200, 200a, and 200b. For example, the cooling water flowing portion 300 may be disposed in two, or three or more along a radial direction of the cooling tubes 200, 200a, and 200b.

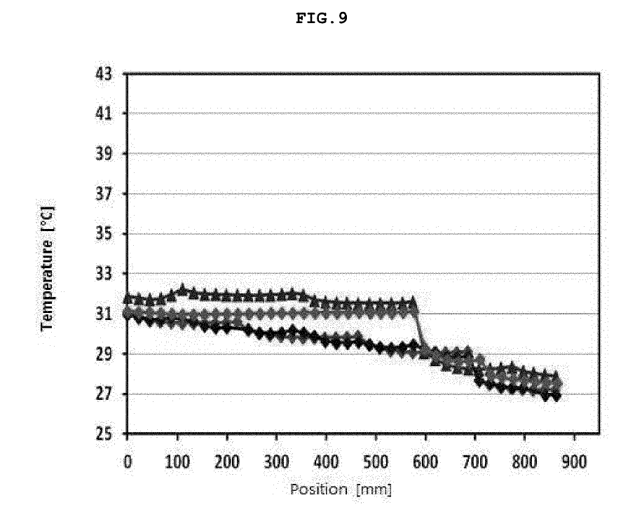

FIG. 9 is a graph illustrating a temperature distribution of locations in vertical and radial directions of a silicon single crystal ingot cooling tube of the present embodiment.

FIG. 9 is a graph illustrating experimental results of measuring a temperature in a longitudinal direction by determining four arbitrary parts of a cooling tube of an embodiment as shown in FIG. 9. Here, an axis x represents a position in a vertical axis direction according to height in mm, and an axis y is a temperature measured in each position in ° C.

It can be seen that a temperature of a cooling tube of an embodiment is lowered as toward an upper portion from a lower portion, and a temperature distribution is distributed uniformly in an arbitrary region. Even in experimental results, it can be understood that a temperature difference is not large in a radial direction.

In a silicon single crystal ingot cooling tube and a silicon single crystal ingot growth apparatus having the same of the present invention, since cooling water flows upward in a zigzag shape after the cooling water flows from an upper portion to a lower portion, a temperature of a single crystal ingot may be uniformly cooled down in a radial direction and a vertical direction, and thus cooling imbalance by bubble generation can be solved by eliminating bubble generated inside via a flow rate control and a narrow flow path.

The features, structures, effects and the like described in the embodiments are included in at least one embodiment of the present invention and are not necessarily limited to only one embodiment. Furthermore, the features, structures, effects and the like illustrated in the embodiments may be combined or modified by other persons skilled in the art to which the embodiments belong. Accordingly, it is to be understood that such combination and modification are included in the scope of the present invention.

### DESCRIPTION OF REFERENCE NUMERALS

200, 200a, 200b: cooling tube

210: inner wall portion

220: outer wall portion

230: top wall portion

240: bottom wall portion

250, 260: cooling water inlet tube

270, 280: cooling water outlet tube

300: cooling water flowing portion

310: downward guide

311: first vertical wall

312: vertical partition wall

313: horizontal partition wall

320: upward guide

321, 321a: first horizontal wall

322: first horizontal spacing wall

323: second horizontal spacing wall

324, 324a: second horizontal wall

325: second vertical wall

What is claimed is:

1. A silicon single crystal ingot cooling tube, comprising:
an inner wall portion for forming a hollow into which a silicon single crystal ingot is inserted;
an outer wall portion spaced apart from the inner wall portion and surrounding the inner wall portion from outside;
a top wall portion and a bottom wall portion for sealing a space portion formed by the inner wall portion and the outer wall portion;
at least one cooling water inlet tube for introducing cooling water into the space portion;
at least one cooling water outlet tube for discharging cooling water flowing along the space portion; and
a cooling water flowing portion for flowing cooling water introduced along the cooling water inlet tube to an upper region of the space portion from a lower region thereof and discharging cooling water to the cooling water outlet tube.

2. The silicon single crystal ingot cooling tube of claim 1, wherein the cooling water flowing portion includes a downward guide for guiding the cooling water introduced into the cooling water inlet tube to a lower portion of the space portion; and a upward guide for flowing the cooling water introduced into the downward guide in a zigzag shape toward an upper portion of the space portion from the lower portion thereof.

3. The silicon single crystal ingot cooling tube of claim 2, wherein the downward guide includes a first vertical wall for dividing the space portion in a vertical direction, a vertical partition wall disposed in parallel with the first vertical wall so as to be adjacent to the upward guide, and a horizontal partition wall extending from the vertical partition wall and disposed in parallel with the bottom wall portion.

4. The silicon single crystal ingot cooling tube of claim 2, wherein a width of the downward guide is the same as a width of the cooling water inlet tube.

5. The silicon single crystal ingot cooling tube of claim 3, wherein the upward guide includes a second vertical wall for dividing the space portion in a vertical direction, a plurality of first horizontal walls each extending in a horizontal direction along a longitudinal direction of the vertical partition wall, and a plurality of second horizontal walls each extending in a horizontal direction along a longitudinal direction of the second vertical wall and disposed between the first horizontal walls.

6. The silicon single crystal ingot cooling tube of claim 5, wherein an interval between the first horizontal walls adjacent to each other is gradually increased as toward an upper portion.

7. The silicon single crystal ingot cooling tube of claim 6, wherein an interval between the first horizontal walls is gradually increased by a width of 10 to 15% as toward an upper portion.

8. The silicon single crystal ingot cooling tube of claim 6, wherein the first horizontal walls are spaced apart from the second vertical wall, and the second horizontal walls are spaced apart from the vertical partition wall.

9. The silicon single crystal ingot cooling tube of claim 8, wherein the first horizontal walls have the same length as that of the second horizontal walls, or the length of the second horizontal walls is shorter than that of the first horizontal walls.

10. The silicon single crystal ingot cooling tube of claim 8, wherein the upward guide is disposed in a horizontal direction so as to be spaced apart from the vertical partition wall along the longitudinal direction of the vertical partition wall, and further includes a plurality of first horizontal spacing walls disposed on an upper portion of the first horizontal walls.

11. The silicon single crystal ingot cooling tube of claim 10, wherein an end portion of the first horizontal spacing wall adjacent to the vertical partition wall is bent downward.

12. The silicon single crystal ingot cooling tube of claim 10, wherein the upward guide is disposed in a horizontal direction so as to be spaced apart from the second vertical wall along the longitudinal direction of the second vertical wall and further includes a plurality of second horizontal spacing walls disposed on an upper portion of the first horizontal spacing walls.

13. The silicon single crystal ingot cooling tube of claim 12, wherein an end portion of the second horizontal spacing wall adjacent to the second vertical wall is bent downward.

14. The silicon single crystal ingot cooling tube of claim 1, wherein a plurality of the cooling water flowing portions are disposed adjacent to the space portion.

15. The silicon single crystal ingot cooling tube of claim 14, wherein the cooling water inlet tube and the cooling water outlet tube are coupled to an upper side of the outer wall portion.

16. A silicon single crystal ingot cooling tube, comprising:
an inner wall portion for forming a hollow;
an outer wall portion spaced apart from the inner wall portion and surrounding the inner wall portion from outside;
a top wall portion and a bottom wall portion for sealing a space portion formed by the inner wall portion and the outer wall portion;
at least one cooling water inlet tube located in an upper portion of the outer wall portion and introducing cooling water into the space portion;
at least one cooling water outlet tube located in the upper portion of the outer wall portion and discharging cooling water flowing along the space portion;
a downward guide for forming a flow path for guiding the cooling water introduced into the cooling water inlet tube to a lower portion of the space portion; and
a upward guide for forming a flow path for discharging the cooling water to the cooling water outlet tube by flowing the cooling water introduced into the downward guide in a zigzag shape toward an upper portion of the space portion from the lower portion thereof.

17. The silicon single crystal ingot cooling tube of claim 16, further comprising:
a first vertical wall for dividing the space portion in a vertical direction;
a vertical partition wall disposed in parallel with the first vertical wall so as to be adjacent to the upward guide; and
a horizontal partition wall extending from the vertical partition wall and disposed in parallel with the bottom wall portion.

18. The silicon single crystal ingot cooling tube of claim 17, further comprising:
a second vertical wall for dividing the space portion in a vertical direction and disposed apart from the first vertical wall;
a plurality of first horizontal walls each extending in a horizontal direction along a longitudinal direction of the vertical partition wall; and
a plurality of second horizontal walls each extending in a horizontal direction along a longitudinal direction of the second vertical wall and disposed between the first horizontal walls.

19. The silicon single crystal ingot cooling tube of claim 18, wherein the silicon single crystal ingot cooling tube is disposed in a horizontal direction so as to be spaced apart from the vertical partition wall along the longitudinal direction of the vertical partition wall, and further includes a plurality of first horizontal spacing walls disposed on an upper portion of the first horizontal walls.

20. A single crystal growth apparatus, comprising:
a chamber;
a crucible disposed inside the chamber and accommodating a silicon melt; and
a silicon single crystal ingot cooling tube,
wherein the silicon single crystal ingot cooling tube comprises:
an inner wall portion for forming a hollow into which a silicon single crystal ingot is inserted;
an outer wall portion spaced apart from the inner wall portion and surrounding the inner wall portion from outside;
a top wall portion and a bottom wall portion for sealing a space portion formed by the inner wall portion and the outer wall portion;
at least one cooling water inlet tube for introducing cooling water into the space portion;
at least one cooling water outlet tube for discharging cooling water flowing along the space portion: and
a cooling water flowing portion for flowing cooling water introduced along the cooling water inlet tube to an upper region of the space portion from a lower region thereof and discharging cooling water to the cooling water outlet tube, and
wherein the silicon single crystal ingot cooling tube cools down a silicon single crystal ingot growing from the crucible.
